(19) United States
(12) Patent Application Publication
(10) Pub. No.: US 2006/0158281 A1
(43) Pub. Date: Jul. 20, 2006

(54) SAW ladder filter

(76) Inventors: Steven Garris, DeBary, FL (US); Joshua Zepess, Bend, OR (US); Riad Mahbub, Apopka, FL (US); Benjamin P. Abbott, Longwood, FL (US)

Correspondence Address: CARL M. NAPOLITANO, PH.D.;ALLEN, DYER, DOPPELT, MILBRATH & GILCHRIST, P.A., 255 SOUTH ORANGE AVE., SUITE 1401, P.O. BOX 3791, ORLANDO, FL, 32802-3791, US

(21) Appl. No.: 11/281,930

(22) Filed: Nov. 17, 2005

Related U.S. Application Data
(60) Provisional application No. 60/629,252, filed on Nov. 18, 2004.

(51) Int. Cl. H03H 9/72; H03H 9/64

(52) U.S. Cl. 333/133; 333/195

(57) ABSTRACT

A SAW filter useful in cellular telephone communications includes SAW resonator elements provided in a series and parallel branches for forming a ladder filter network, and SAW resonator elements connected in parallel and provided in the series branch of the SAW filter for providing improved ESD protection to the SAW filter. The SAW filter is effectively used with an ESD protection circuit and a triplexer for receiving and separating low, high, and bandpass frequencies.

### CROSS-REFERENCE TO RELATED APPLICATION

This application claims the benefit of U.S. Provisional Application No. 60/629,252 for “SAW Ladder Filter” having filing date Nov. 18, 2004, the disclosure of which is incorporated herein by reference in its entirety, all being commonly owned.

### FIELD OF INVENTION

The present invention generally relates to surface acoustic wave (SAW) devices, and particularly to a SAW device exhibiting improved electrostatic discharge (ESD) characteristics.

### BACKGROUND

SAW devices are widely used in communication systems. The small size, low cost and ease of high-volume manufacturing lend SAW devices to be readily adapted for mobile phones. A number of SAW devices are used as front-end filters, which are either connected to the antenna of mobile telephones or are placed very close to the antenna. These SAW devices are duplexers and triplexers. The SAW duplexer includes a dual SAW bandpass filter which enables the communication system to perform concurrent reception and transmission of the signal. The triplexer is used for the reception and separation of the incoming signals into three separated frequency components. The SAW triplexer comprises a low-pass filter network for the reception and separation of the incoming signal in a low frequency band, a high-pass network to separate the signal into a high frequency band, and a SAW bandpass filter for the reception and separation of the incoming signal at a frequency band located between that of the low and high bands of the signal.

A SAW ladder filter configuration, because of its low loss and great power handling capability, is commonly used for the implementation of SAW duplexer and triplexer. One example of a SAW ladder configuration is disclosed in U.S. Pat. RE37, 375 to Satoh et al.

SAW devices such as duplexers and triplexers being used for front end filtering are highly sensitive to electrostatic discharge (ESD). ESD damage is usually caused by one of three events including a direct electrostatic discharge to the device, electrostatic discharge from the device to other components in the circuit, or it may result from field-induced discharge. In mobile phone applications, common ESD failure results from direct electrostatic discharge from a human body. There is generally a significant amount of charge build up in a human body through mechanical motion like walking across a carpet floor. The ESD voltage in the human body is then discharged across the phone electronic circuitry, when one grabs the phone touching the antenna. The ability of the device to dissipate the energy of the discharge or the ability to withstand the high voltage level is a measurement of the device ESD handling capability. Typically, for a mobile phone system, the SAW ESD handling capability must withstand a voltage peak of 8 kV contact discharge. While 8 kV is acceptable for mobile phone applications, it is desirable among several phone manufacturers to have the SAW device able to handle a voltage discharge in excess of 10 kV.

### SUMMARY

A SAW filter in keeping with the teachings of the present invention may comprise a first SAW resonator element provided in a series branch of the SAW filter and a second SAW resonator element provided in a parallel branch of the SAW filter, wherein the first and second SAW resonator elements form a ladder filter network having an input signal terminal and an output signal terminal, and at least two parallel connected third and fourth SAW resonator elements provided in the series branch of the SAW filter and connected to at least one of the input and the output terminals. Each SAW resonator element may comprise a SAW transducer carried on a piezoelectric substrate surface between opposing reflectors. The SAW transducer and the opposing reflectors generally include a plurality of metal electrodes disposed on the substrate surface. Each of the metal electrodes may comprise aluminum or an aluminum alloy material. Further, the metal electrodes may comprise a uniform thickness ranging from 5% to 12% of a wavelength of a propagated SAW. Each of the third and fourth SAW resonator elements may have the same transducer length and aperture width.

The pair of parallel resonator elements at the input terminal of the SAW ladder filter effectively provides a dual path for current drain thereby reducing the current density across the SAW transducer and effectively adding improved ESD protection for the filter. Further, the SAW filter may be employed in a SAW triplexer comprising an ESD protection circuitry to further enhance the ESD voltage handling capability. The ESD circuitry may include a diode or a varistor.

An embodiment employing the SAW filter may include a SAW triplexer that receives signals in at least three frequency bands and output the signal components to its appropriate signal processing ports. The triplexer may comprise a low pass filter connected to an input terminal for reception and separation of an incoming signal of a low frequency band of interest, a high pass filter connected to the input terminal for the reception and separation of the incoming signal of the highest frequency band of interest, and a SAW bandpass filter. The SAW bandpass filter may comprise series and parallel branch resonator elements forming a ladder filter configuration connected to the input terminal for the reception and separation of the incoming signal at the frequency band located between the low and the high bands of the signal, and the input terminal connected to an ESD protection circuitry comprising at least one of a diode and varistor. Yet further, the SAW triplexer may include the resonator element comprised of SAW transducer and reflectors having metal electrodes disposed upon a piezoelectric substrate. The input terminal may be connected to a series branch resonator element comprising of at least two parallel-connected resonators.

### BRIEF DESCRIPTION OF DRAWINGS

Embodiments of the invention are described, by way of example, with reference to the accompanying drawings in which:

FIG. 1 is a partial schematic layout of a SAW ladder filter in keeping with the teachings of the present invention;

FIGS. 2 and 2A illustrate a SAW single transducer disposed between reflectors as a SAW single pole resonator manufactured layout structure, and an equivalent circuit representation, respectively;

FIG. 3 illustrates a SAW ladder filter configuration including series cascaded resonator elements provided in a series branch and a parallel pair provided in a parallel branch thereof;

FIG. 4 is a partial schematic illustrating an ESD test setup;

FIG. 5 is a schematic layout of one known SAW ladder filter illustrating resonator elements arranged in a series branch and a parallel branch;

FIG. 6 is a partial schematic view of a SAW triplexer having ESD protection according to the teachings of the present invention;

FIG. 7 is a partial schematic view of a SAW triplexer having a varistor ESD protection according to the teachings of the present invention; and

FIG. 8 is a table illustrating SAW ESD performance data.

### DETAILED DESCRIPTION OF EMBODIMENTS

The present invention will now be described more fully with reference to the accompanying drawings in which alternate embodiments of the invention are shown and described. It is to be understood that the invention may be embodied in many different forms and should not be construed as limited to the illustrated embodiments set forth herein. Rather, these embodiments are provided so that this disclosure may be thorough and complete, and will convey the scope of the invention to those skilled in the art.

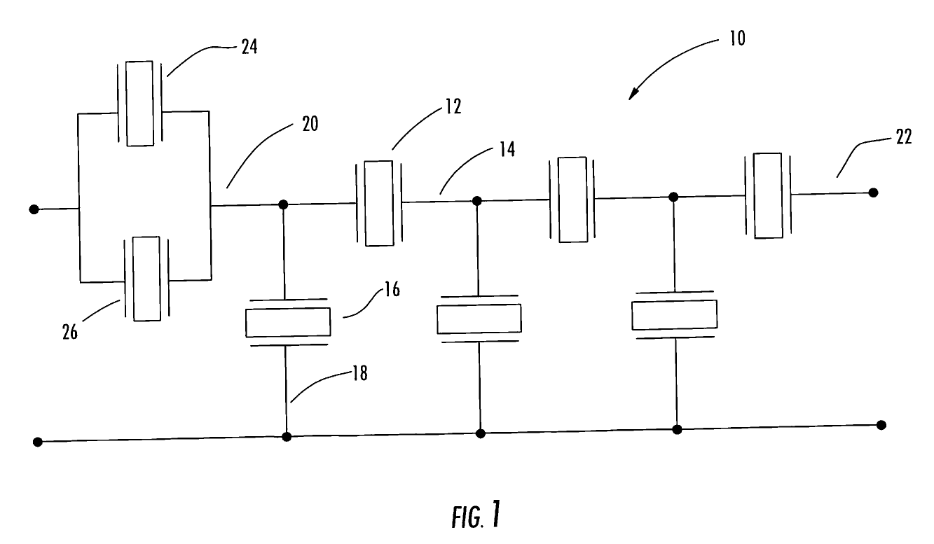

With reference initially to FIG. 1, one embodiment of the present invention, as herein described by way of example, includes a SAW filter 10 including a first SAW resonator element 12 provided in a series branch 14 of the SAW filter and a second SAW resonator element 16 provided in a parallel branch 18 of the SAW filter, wherein the first and second SAW resonator elements form a ladder filter network having an input signal terminal 20 and an output signal terminal 22. For the embodiment herein described by way of example, at least two parallel connected third and fourth SAW resonator elements 24, 26 are provided in the series branch 14 of the SAW filter 10 and connected to the input terminal 20, as herein described by way of example, or alternatively at the output terminal 22.

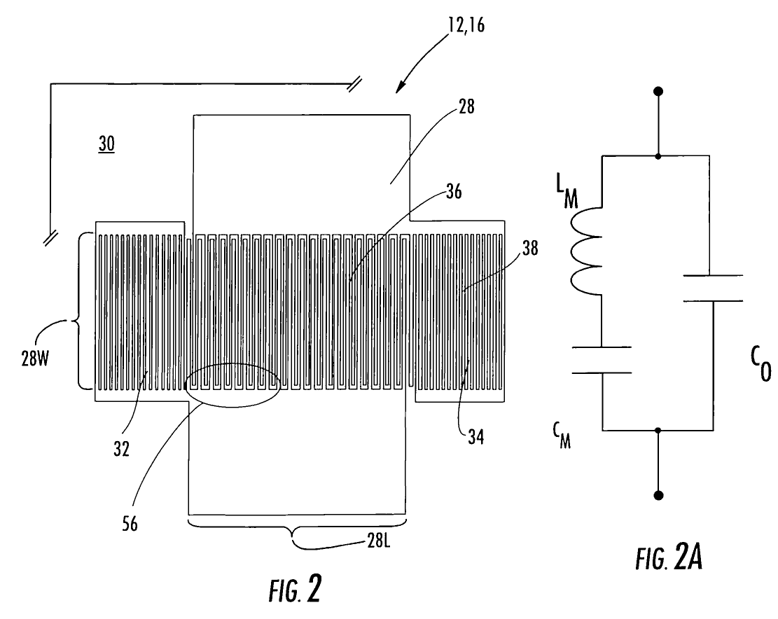

With reference to FIG. 2, and as herein described, each SAW resonator element 12, 16, 24, 26 may comprise a SAW transducer 28 carried on a piezoelectric substrate 30 between opposing reflectors 32, 34. The SAW transducer 28 and the opposing reflectors 32, 34 include a plurality of metal electrodes 36, 38 respectively disposed on a surface of the substrate 30. Each of the metal electrodes may comprise aluminum or an aluminum alloy material. In addition, one embodiment of the invention herein described and tested includes metal electrodes having a uniform thickness ranging from 5% to 12% of a wavelength of a propagated SAW. Yet further, each of the third and fourth SAW resonator elements 24, 26 may have the same transducer length 28L and aperture width 28W. The commonly used piezoelectric substrates are lithium tantalate and lithium niobate.

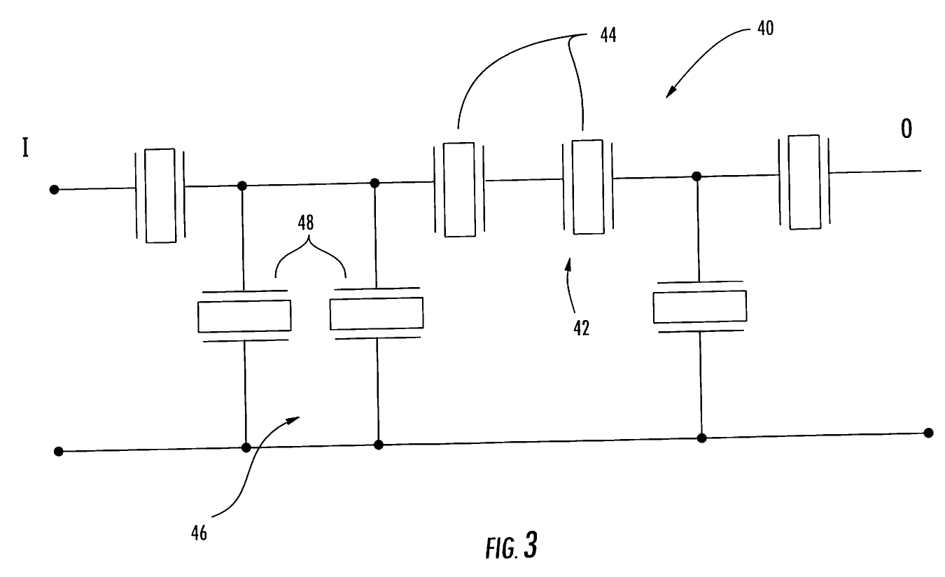

By way of example and with reference to FIG. 3, a SAW ladder filter 40 may include multiple series resonator elements 42, as above described with reference to FIG. 1 as the first SAW resonator element 12 configured in a series cascaded of two resonator elements 44. The cascaded resonator elements 44 may have an aperture twice as large as the single resonator element 12 thereby providing an equivalent capacitance. The series cascaded resonator elements 44 enhance heat absorption and dissipation, and thus improve power-handling capability of the SAW device. As illustrated with continued reference to FIG. 3, a parallel SAW resonator element 46 may also be arranged in as a parallel pair of resonator elements 48.

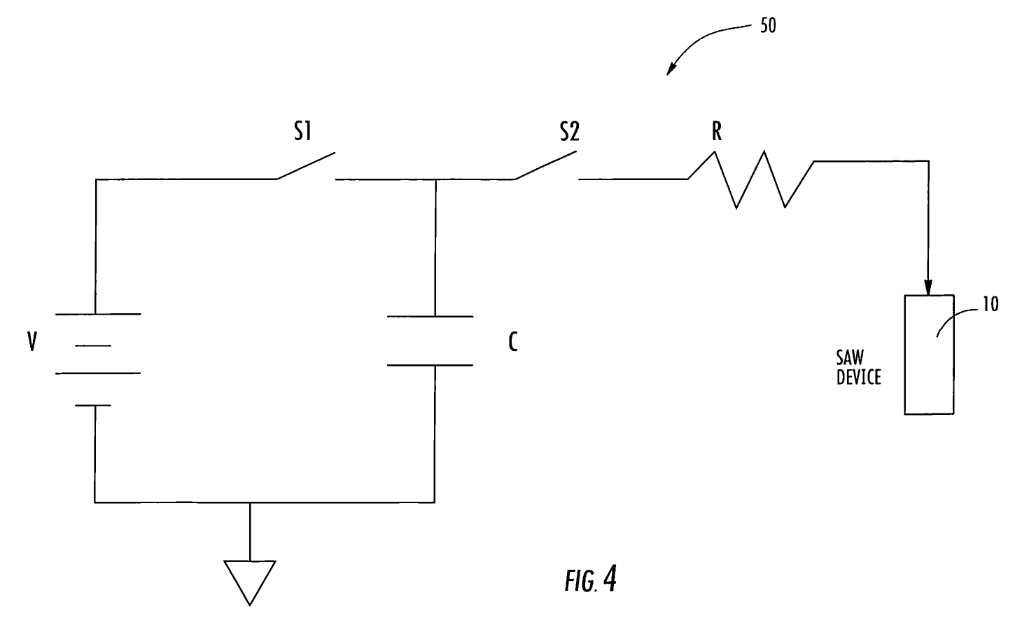

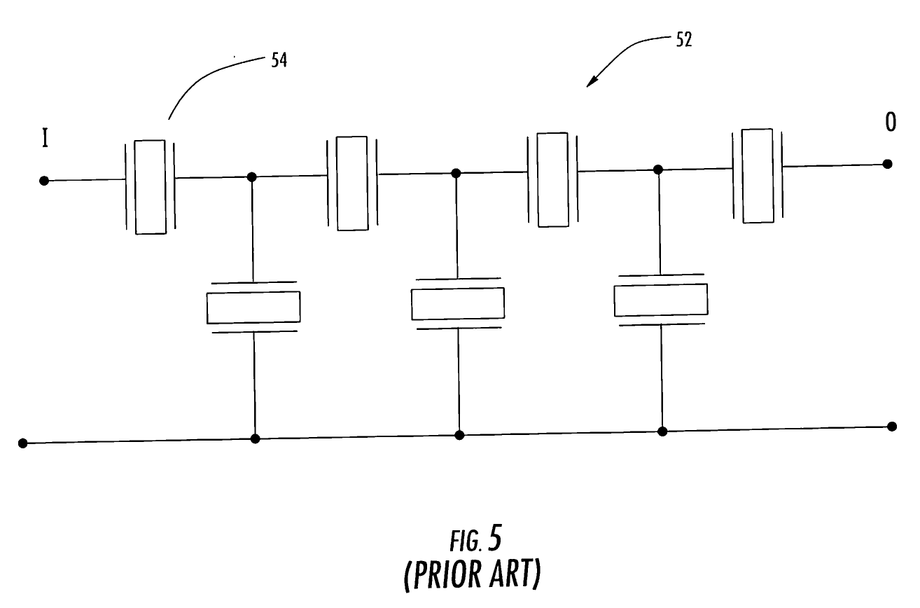

As above described, a SAW ESD handling capability for a mobile telephone must typically withstand a voltage peak of 8 kV contact discharge. While 8 kV is acceptable for mobile phone applications, it is desirable among several phone manufacturers to have the SAW device able to handle a voltage discharge in excess of 10 kV. By way of example, and with reference to FIG. 4, one ESD test set up 50 used to test whether the SAW device 10 in a triplexer can withstand an 8 kV discharge is illustrated. The capacitor (C) is charged by the voltage source (V) by closing a first switch (S1) until the capacitor (C) reaches 8 kV. Switch (S1) is then opened. A probe is then allowed to touch an antenna of a phone carrying the SAW filter 10 and a second switch (S2) is then closed to discharge the high voltage across the device having the SAW filter. By way of example with regard to typical ladder filters as illustrated with reference to FIG. 5, the triplexer being tested that uses the typical SAW configuration 52 consistently failed. Failure analysis on SAW triplexers indicates that damage is at the SAW input series resonator element 54. The damage to the SAW filter 52 generally results from a relatively large current spike draining through the SAW transducer in very short time duration. The ESD damage can cause catastrophic failure to the SAW device by melting some of the electrode fingers 56 of the SAW transducer or by blowing a hole in the piezoelectric substrate 30, as illustrated with reference again to FIG. 2.

Embodiments of the present invention, as above described with reference to FIGS. 1 and 3 by way of example, provide SAW ladder filter embodiments that can absorb and withstand a higher than normal ESD voltage. Further, solutions for allowing a SAW triplexer to handle greater ESD voltage discharge will also be described herein by way of example.

With reference again to FIGS. 1 and 2, the resonator elements 12, 16 may be also described in an equivalent lumped element circuit as illustrated with reference to FIG. 2A. Co represents an electrostatic capacitance while Cm and Lm represent an equivalent motional element of the resonator. Ignoring the resistance of the resonator, the equivalent combinations of these elements provide a good estimate of the resonator impedance. With reference again to FIG. 1, the parallel element pair 24, 26 at the input terminal 20 of the SAW ladder filter 10 is a series element. Each resonator element 24, 26 of the parallel pair of elements in the series branch has approximately the same impedance for the embodiment herein described, which implies that the transducer length and aperture of each resonator element of the resonator pair is approximately the same. With an ESD voltage discharge, the parallel resonator elements 24, 26 at the input series branch of the SAW ladder filter 10 provide a dual current path such that the current density across the each resonator is reduced approximately by half, thereby enhancing the ESD handling capability. The parallel resonator pairs incorporated at the input series element of the SAW ladder filter thus operate as a current divider. As above described, one embodiment includes the transducer lengths 28L and aperture widths 28W of the parallel resonator pair are as close as practically possible to each other. However, it has been shown that a 25% difference in transducer length or aperture would still provide an adequate improvement in the handling of ESD. The SAW ladder filter 10 may be connected directly to an antenna, indirectly through a matching network of inductors and capacitors, or through an ESD protection circuitry. The protection circuitry may comprise a diode or a varistor, by way of example. The ESD protection circuitry would enable the SAW device to withstand additional ESD voltage discharge.

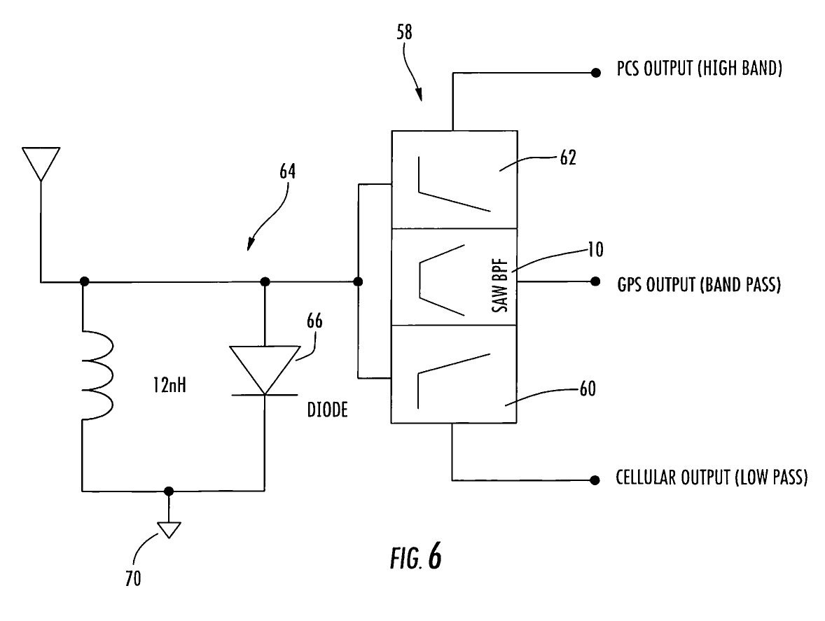

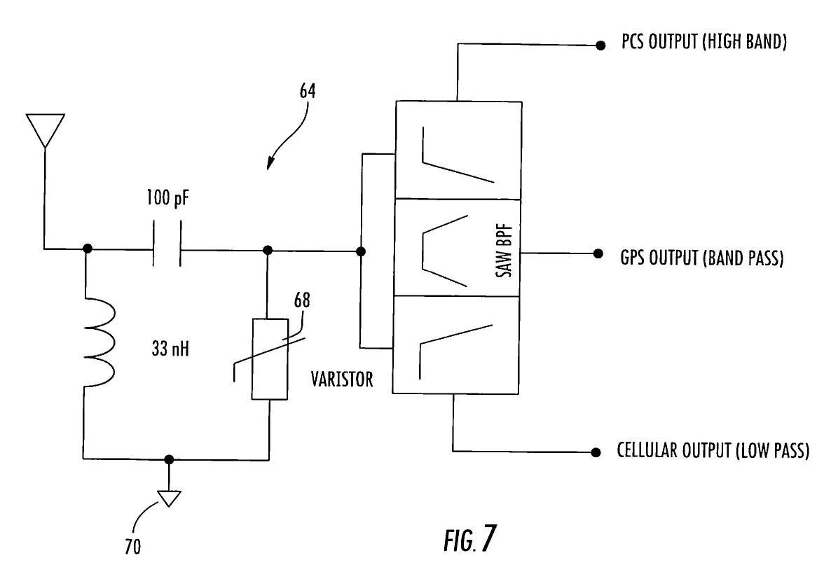

A SAW ladder filter configuration, because of its low loss and great power handling capability, is effectively used for the implementation of SAW duplexers and triplexers. With reference now to FIG. 6, one embodiment of the present invention may include the SAW filter 10 employed with a triplexer 58 having a low pass filter network 60, a high pass filter network 62, and the SAW filter 10 operating as a SAW bandpass filter. The low pass filter network 60 may include L-C components and performs the function of receiving and separation of incoming signal with the lowest desired frequency band. The high pass filter network 62 also includes L-C components and performs the function of receiving and separation of incoming signal with the highest desired frequency band. One triplexer may be as described in U.S. patent application Ser. No. 10/950,958, the disclosure of which in herein incorporated by reference. The SAW filter 10 provides the reception and separation of the incoming signal at a frequency band located between that of the low and the high bands of the signal. The triplexer 58 may be connected to an ESD protection circuit 64, which may comprise a diode 66 or a varistor 68 as illustrated with reference again to FIG. 6, and to FIG. 7. The diode 66 or the varistor 68 may be connected directly or indirectly to a ground node 70. An inductor 72 may be added to rematch any distortion of the triplexer 58 due to addition of the diode or varistor.

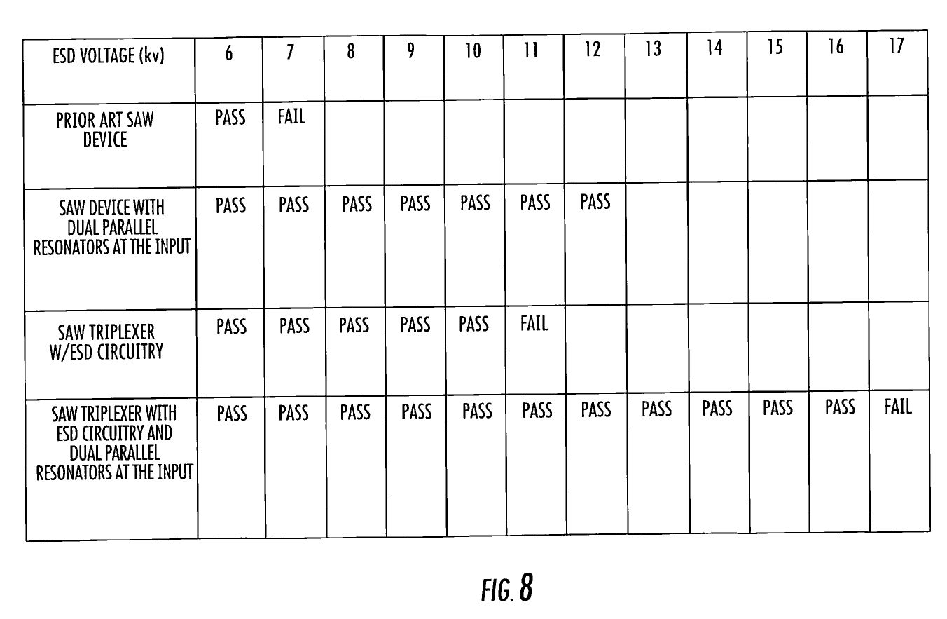

By way of further example, FIG. 3 includes a table illustrating test results covering prior art SAW ladder filter 52 such as that described with reference to FIG. 5, and the SAW ladder filter 10 in which the input series element comprises two parallel resonators, as disclosed, while it is to be understood that more than two may be employed. The two filters 10, 52 are tested under conditions with and without the ESD protection circuit 64. The prior art SAW filter 52 fails to withstand a ESD voltage greater than 7 kV while the present invention can survive an ESD voltage up to 12 kV. With the application of the use of a diode or a varistor as an ESD protection circuit, as illustrated by way of example with reference again to FIGS. 6 and 7, the SAW triplexer 58 can withstand the ESD voltage of greater than 16 kV. It is quite clear from the ESD performance data as presented in FIG. 8 that the parallel connection of the dual resonators shows a significant improvement over the regular series single resonator element.

Many modifications and other embodiments of the invention will come to the mind of one skilled in the art having the benefit of the teachings presented in the foregoing descriptions and the associated drawings and photos. Therefore, it is to be understood that the invention is not to be limited to the specific embodiments disclosed, and that modifications and alternate embodiments are intended to be included within the scope of the claims supported by this specification.

That which is claimed is:

1. A SAW filter comprising:
a first SAW resonator element provided in a series branch of the SAW filter and a second SAW resonator element provided in a parallel branch of the SAW filter, wherein the first and second SAW resonator elements form a ladder filter network having an input signal terminal and an output signal terminal; and
at least two parallel connected third and fourth SAW resonator elements provided in the series branch of the SAW filter and connected to at least one of the input and the output terminals.

2. A SAW filter according to claim 1, wherein each SAW resonator element comprises a SAW transducer carried on a piezoelectric substrate surface between opposing reflectors.

3. A SAW filter according to claim 2, wherein each of the SAW transducer and the opposing reflectors includes a plurality of metal electrodes disposed on the substrate surface.

4. A SAW filter according to claim 3, wherein each of the plurality of the metal electrodes comprises one of aluminum and aluminum alloy material.

5. A SAW filter according to claim 3, wherein the metal electrodes each comprise a uniform thickness ranging from 5% to 12% of a wavelength of a SAW being propagated thereacross.

6. A SAW filter according to claim, 1, wherein each of the third and fourth SAW resonator elements has the same transducer length and aperture width.

7. A SAW filter according to claim 1, further comprising a series cascaded resonator element combination provided in the series branch, the series cascaded resonator element combination having at least two SAW resonator elements therein.

8. A SAW filter according to claim 1, further comprising a parallel pair resonator element combination within the parallel branch, the parallel pair resonator element combination having at least two SAW resonator elements therein.

9. A SAW filter according to claim 1, further comprising an ESD protection circuit connected to an input of the third SAW resonator element for operation with the ladder filter, the ESD protection circuit including at least one of a diode and a varistor.

10. A SAW filter according to claim 1, wherein at least one of the input signal terminal and the output signal terminal is operable with a low pass filter for receiving and separating an incoming signal into a preselected low frequency band and a high pass filter for receiving and separating the incoming signal into a preselected high frequency band.

11. A SAW triplexer operable for receiving signals in at least three frequency bands, the SAW triplexer comprising:
a low pass filter connected to an input terminal for receiving and separating an incoming signal into a preselected low frequency band;
a high pass filter connected to the input terminal for receiving and separating the incoming signal into a preselected high frequency band; and
a SAW bandpass filter having SAW resonator elements provided in series and parallel branches of the SAW bandpass filter, wherein the SAW resonator elements form a ladder filter network having an input signal terminal and an output signal terminal for the receiving and separating of the incoming signal at a frequency band located between the preselected low and the preselected high frequency bands, and wherein at least two parallel connected third and fourth SAW resonator elements provided in the series branch of the SAW filter and connected to at least one of the input and the output terminals.

12. A SAW triplexer according to claim 11, further comprising an ESD protection circuit connected to the input terminal, the ESD protection circuit including at least one of a diode and a varistor.

13. A SAW triplexer according to claim 11, wherein each SAW resonator element comprises a SAW transducer carried on a piezoelectric substrate surface between opposing reflectors.

14. A SAW filter according to claim 13, wherein each of the SAW transducer and the opposing reflectors includes a plurality of metal electrodes disposed on the substrate surface.

15. A SAW filter according to claim 14, wherein each of the plurality of the metal electrodes comprises one of aluminum and aluminum alloy material.

16. A SAW filter according to claim 11, wherein each of the third and fourth SAW resonator elements has the same transducer length and aperture width.

17. A SAW filter according to claim 11, further comprising a series cascaded resonator element combination provided in the series branch, the series cascaded resonator element combination having at least two SAW resonator elements therein.

18. A SAW filter according to claim 11, further comprising a parallel pair resonator element combination within the parallel branch, the parallel pair resonator element combination having at least two SAW resonator elements therein.
